(19) United States
(12) Patent Application Publication
(10) Pub. No.: US 2009/0014876 A1
(43) Pub. Date: Jan. 15, 2009

(54) Wafer level stacked package having via contact in encapsulation portion and manufacturing method thereof

(75) Inventors: Cheul-joong Youn, Seoul (KR); Eun-chul Ahn, Yongin-si (KR); Young-Lyong Kim, Seongnam-si (KR); Jong-ho Lee, Asan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/216,095

(22) Filed: Jun. 30, 2008

(30) Foreign Application Priority Data
Jul. 13, 2007 (KR) 10-2007-0070775

(51) Int. Cl. H01L 23/488; H01L 21/56

(52) U.S. Cl. 257/738; 438/109; 257/E21.502; 257/E23.023

(57) ABSTRACT

Provided are a wafer level stacked package with a via contact in an encapsulation portion, and a manufacturing method thereof. A plurality of semiconductor chips and encapsulation portions may be vertically deposited and electrically connected through a via contact that may be vertically formed in the encapsulation portion. Thus, an effective fan-out structure may be produced, vertical deposition may be available regardless of the type of a semiconductor device, and productivity may be improved.

### PRIORITY STATEMENT

This application claims priority under 35 U.S.C. §1.119 to Korean Patent Application No. 10-2007-0070775, filed on Jul. 13, 2007, in the Korean Intellectual Property Office, the entire contents of which are incorporated herein by reference.

### BACKGROUND

1. Field

Example embodiments relate to a semiconductor package and a manufacturing method thereof, and more particularly, to a wafer level stacked package with a via contact in an encapsulation portion and a manufacturing method thereof.

2. Description of Related Art

Conventionally, the high integration of a semiconductor device has been achieved by either decreasing a line width in a design rule during a wafer manufacturing process or three-dimensionally arranging electronic parts such as a transistor or capacitor to pack a larger number of circuit parts in a limited wafer area. Recently, a method of increasing the integration by mounting a larger number of semiconductor chips in a single semiconductor package by vertically depositing a plurality of thin semiconductor chips has been introduced. The method of increasing the integration of a semiconductor device through a semiconductor package manufacturing technology is being widely studied because the method has various merits in terms of costs, the time needed for research and development, and the process implementation availability, compared to the method of increasing the integration during the wafer manufacturing process.

In particular, research involving a system in package (SIP) that may produce a single integrated semiconductor package by depositing semiconductor chips having a microprocessor or microcontroller with a semiconductor chip having a memory function, or the semiconductor chip having a memory function with a semiconductor chip having a logic function is being widely performed. However, a semiconductor package using semiconductor chips deposited in a vertical direction may cause difficulty in implementing “fan-out”, i.e., the effective expansion of an interval between neighboring external electrical connections that are connected to narrowly spaced bond pads of a semiconductor.

Also, in a semiconductor package using vertically deposited semiconductor chips, electric connections between the vertically deposited semiconductor chips may be made using a wire bonding technology. Problems may occur with such a package, when many wires are used to connect semiconductor chips to connection points, or bond fingers, on a printed circuit board. Specifically, the vertically deposited semiconductor chips may have an overhang structure in which a space may be provided along the edge of a semiconductor chip between an upper semiconductor chip and a lower semiconductor chip, in order to secure a wire bonding space. When wire bonding is used on a semiconductor chip having a space in a lower portion, damage (e.g., a crack) may occur at the edge of a semiconductor chip.

Finally, electrically connecting semiconductor chips that are vertically deposited through the use of a through-silicon via contact that vertically penetrates bond pads of the deposited semiconductor chips has been used. Such technology may cause problems, for example, the manufacturing process may be complicated, manufacturing costs may be high, and the deposition of different types of semiconductor chips may be restricted.

### SUMMARY

To solve the above and/or other problems, example embodiments provide a wafer level stacked package with a via contact in an encapsulation portion.

Example embodiments provide a method of manufacturing a wafer level stacked package with a via contact in an encapsulation portion.

According to example embodiments, a wafer level stacked package with a via contact in an encapsulation portion may comprise a first semiconductor chip that may have an active region facing upward, a first encapsulation portion that may be formed along an edge of the first semiconductor chip, a first wiring pattern that may be connected to bond pads of the first semiconductor chip above the first semiconductor chip and extending upward from the first encapsulation portion, a second semiconductor chip that may be mounted on the first semiconductor chip using an adhesive member such that an active region of the second semiconductor chip faces upward, a second encapsulation portion that may be formed along an edge of the second semiconductor chip above the first encapsulation portion, a second wiring pattern that may be connected to bond pads of the second semiconductor chip above the second semiconductor chip and extending upward from the second encapsulation portion, a via contact that may connect the first wiring pattern and the second wiring pattern in the second encapsulation portion, and protruding connection terminals that may be attached to the second wiring pattern.

The wafer level stacked package may further comprise a protective layer formed on a bottom surface of the first semiconductor chip and the first encapsulation portion. The protective layer may be formed of the same material as that of the first encapsulation portion. The protective layer may be formed of a material exhibiting a superior heat transfer characteristic that may be different from that of the first encapsulation portion.

The wafer level stacked package may further comprise one or more additional semiconductor chips, one or more additional encapsulation portions, and one or more additional wiring patterns that may be connected through the via contact between the first semiconductor chip and the second semiconductor chip.

The sizes of the first semiconductor chip, the second semiconductor chip, and other semiconductor chip may be different from one another. The via contact connecting the first wiring pattern, the second wiring pattern, and other wiring pattern may be connected through a single path or a plurality of paths.

According to example embodiments, a wafer level stacked package with a via contact in an encapsulation portion may comprise a first semiconductor chip with an active region facing upward, a first encapsulation portion may be formed along an edge of the first semiconductor chip, a first wiring pattern may be connected to bond pads of the first semiconductor chip above the first semiconductor chip and extending upward from the first encapsulation portion, a second semiconductor chip may be electrically connected to the first semiconductor chip via a bump with a size smaller than that of the first semiconductor chip, a second encapsulation portion may be formed along an edge of the second semiconductor chip, a third semiconductor chip may be mounted on the second semiconductor chip using an adhesive member such that an active region of the third semiconductor chip faces upward, a third encapsulation portion may be formed along an edge of the third semiconductor chip above the second encapsulation portion, a third wiring pattern may be connected to bond pads of the second semiconductor chip above the third semiconductor chip and extending upward from the third encapsulation portion, a via contact may connect the first wiring pattern and the third wiring pattern in the second and third encapsulation portions, and protruding connection terminals may be attached to the third wiring pattern.

The wafer level stacked package may further comprise a protective layer formed on bottom surfaces of the first semiconductor chip and the first encapsulation portion.

According to example embodiments, a method of manufacturing a wafer level stacked package with a via contact in an encapsulation portion may comprise mounting a plurality of first semiconductor chips on a carrier that may have an adhesive force such that an active region of the first semiconductor chip faces upward, forming a first encapsulation portion that may have the same height as that of the first semiconductor chip on the carrier, forming a first wiring pattern that may be connected to bond pads of the first semiconductor chip and extending to the first encapsulation portion, mounting a second semiconductor chip on the first semiconductor chip where the first wiring pattern may be formed, using an adhesive member, such that an active region of the second semiconductor chip faces upward, forming a second encapsulation portion that may have the same height as that of the second semiconductor chip on the first encapsulation portion, forming a via contact by forming a contact hole that may expose the first wiring pattern in the second encapsulation portion and filling the contact hole with a conductive material, and forming a second wiring pattern that may be connected to bond pads of the second semiconductor chip, while extending the second wiring pattern to the second encapsulation portion, and electrically connecting the second wiring pattern to the via contact.

The first and second encapsulation portions may be formed in a method selected among molding, printing, spin coating, and jetting methods. The contact hole in the second encapsulation portion may be formed in a laser drilling method. After forming the second wiring pattern, the carrier may be removed. After forming the second wiring pattern, the protruding connection terminal may be attached to the second wiring pattern. After the forming of the second wiring pattern, a protective layer may be formed on bottom surfaces of the first semiconductor chip and the first encapsulation portion.

Another semiconductor chip, another encapsulation portion, and another wiring pattern between the first and second semiconductor chips may be formed.

The sizes and thicknesses of the first semiconductor chip, the second semiconductor chip, and the other semiconductor chip may be the same or different from one another. The first wiring pattern, the other wiring pattern, and the second wiring pattern may extend upward though one or more paths.

One or more first semiconductor chips may be connected to the second semiconductor chip.

The via contact may be formed through a one-time contact hole forming process after the second encapsulation portion may be formed. The via contact may be primarily formed after another encapsulation portion may be formed on the first encapsulation portion and secondly formed after the second encapsulation portion may be formed.

According to example embodiments, a method of manufacturing a wafer level stacked package with a via contact in an encapsulation portion may comprise mounting a first semiconductor chip on a carrier using an adhesive force such that an active region of the first semiconductor chip faces upward, forming a first encapsulation portion that may completely cover the first semiconductor chip on the carrier, forming a first wiring pattern that may be connected to bond pads of the first semiconductor chip and extending to the first encapsulation portion, by removing the carrier and arranging the active region of the first semiconductor chip to face upward, mounting a second semiconductor chip on the first semiconductor chip where the first wiring pattern may be formed, using an adhesive member, such that an active region of the second semiconductor chip faces upward, forming a second encapsulation portion that may have the same height as that of the second semiconductor chip on the first encapsulation portion, forming a via contact by forming a contact hole that may expose the first wiring pattern in the second encapsulation portion and filling the contact hole with a conductive material, and forming a second wiring pattern that may be connected to bond pads of the second semiconductor chip, while extending the second wiring pattern to the second encapsulation portion, and electrically connecting the second wiring pattern to the via contact.

According to example embodiments, a method of manufacturing a wafer level stacked package having a via contact in an encapsulation portion may comprise mounting a plurality of first semiconductor chips on a carrier using an adhesive force such that an active region of the first semiconductor chip faces upward, forming a first encapsulation portion that may have the same height as that of the first semiconductor chip on the carrier, forming a first wiring pattern that may be connected to some of bond pads of the first semiconductor chip, while the first wiring pattern may extend to the first encapsulation portion, mounting a second semiconductor chip that may have a size smaller than that of the first semiconductor chip, while the second semiconductor chip may be connected to the other bond pads of the first semiconductor chip and not connected to the first wiring pattern, forming a second encapsulation portion that may have the same height as that of the second semiconductor chip on the first encapsulation portion, mounting a third semiconductor chip by using an adhesive member on the second semiconductor chip where the second encapsulation portion may be formed such that an active region of the third semiconductor chip faces upward, forming a third encapsulation portion that may have the same height as that of the third semiconductor chip on the second encapsulation portion, forming a via contact by forming a contact hole that may expose the first wiring pattern in the second and third encapsulation portions and filling the contact hole with a conductive material, and forming a third wiring pattern that may be connected to bond pads of the third semiconductor chip, while the third wiring pattern may extend to the third encapsulation portion while being electrically connected to the via contact.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIGS. 1 to 9 are cross-sectional views that show a method of manufacturing a wafer level stacked package with a via contact in an encapsulation portion according to example embodiments.

FIG. 10 is a cross-sectional view of the wafer level stacked package manufactured according to example embodiments.

FIGS. 11 to 15 are cross-sectional views that show a method of manufacturing a wafer level stacked package with a via contact in an encapsulation portion according to example embodiments.

FIG. 16 illustrates a first modified example of a wafer level stacked package manufactured according to example embodiments.

FIG. 17 illustrates a second modified example of the wafer level stacked package manufactured according to example embodiments.

FIG. 18 illustrates a third modified example of the wafer level stacked package manufactured according to example embodiments.

FIG. 19 illustrates a fourth modified example of the wafer level stacked package manufactured according to example embodiments.

FIG. 20 illustrates a fifth modified example of the wafer level stacked package manufactured according to example embodiments.

FIG. 21 illustrates a sixth modified example of the wafer level stacked package manufactured according to example embodiments.

FIG. 22 is a cross-sectional view that illustrates a wafer level stacked package with a via contact in an encapsulation portion according to example embodiments.

FIG. 23 is a cross-sectional view that illustrates an application of a modified example of the wafer level stacked package according to example embodiments.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

### First Example Embodiment

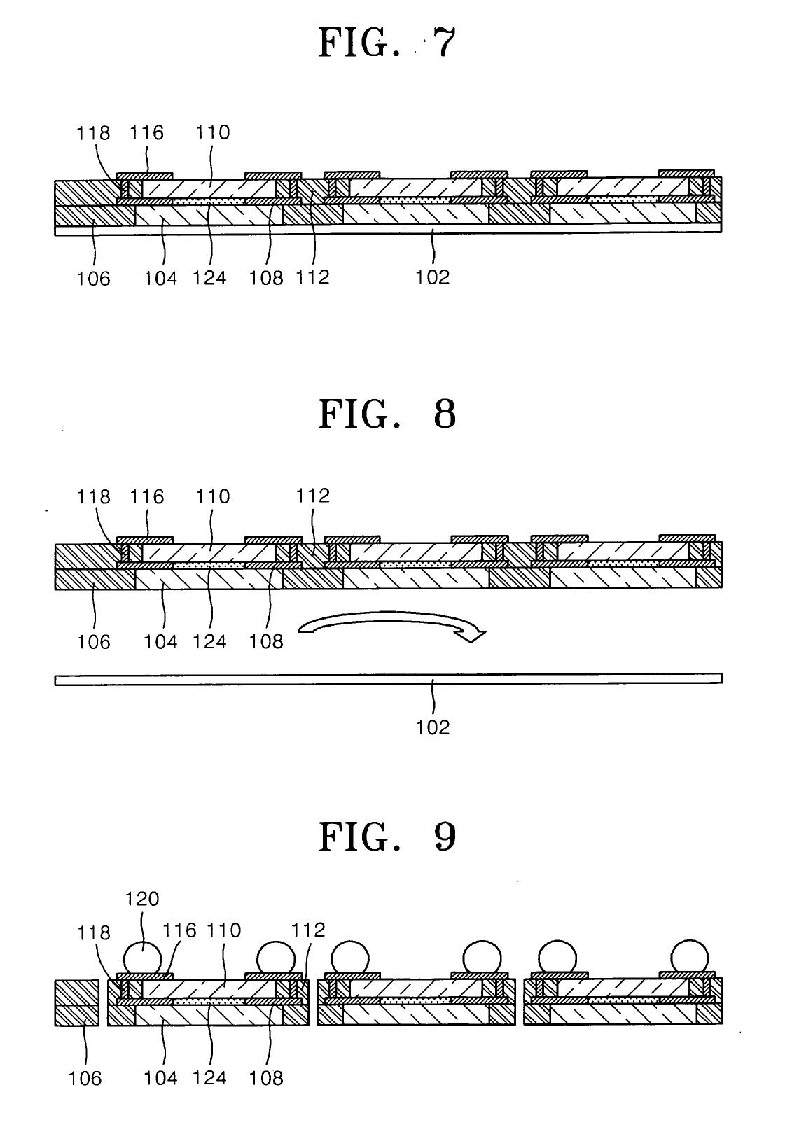

FIGS. 1 to 9 are cross-sectional views that show a method of manufacturing a wafer level stacked package with a via contact in an encapsulation portion according to example embodiments. Referring to FIG. 1, according to a manufacturing method of a wafer level stacked package according to example embodiments, a plurality of first semiconductor chips 104 may be mounted on a carrier 102 having an adhesive force such that an active region A of each of the first semiconductor chips 104 may face upward. The carrier 102 is preferably a solid substrate where an adhesive layer (not shown) may have an adhesive force that varies according to light or heat, which may be formed on carrier 102.

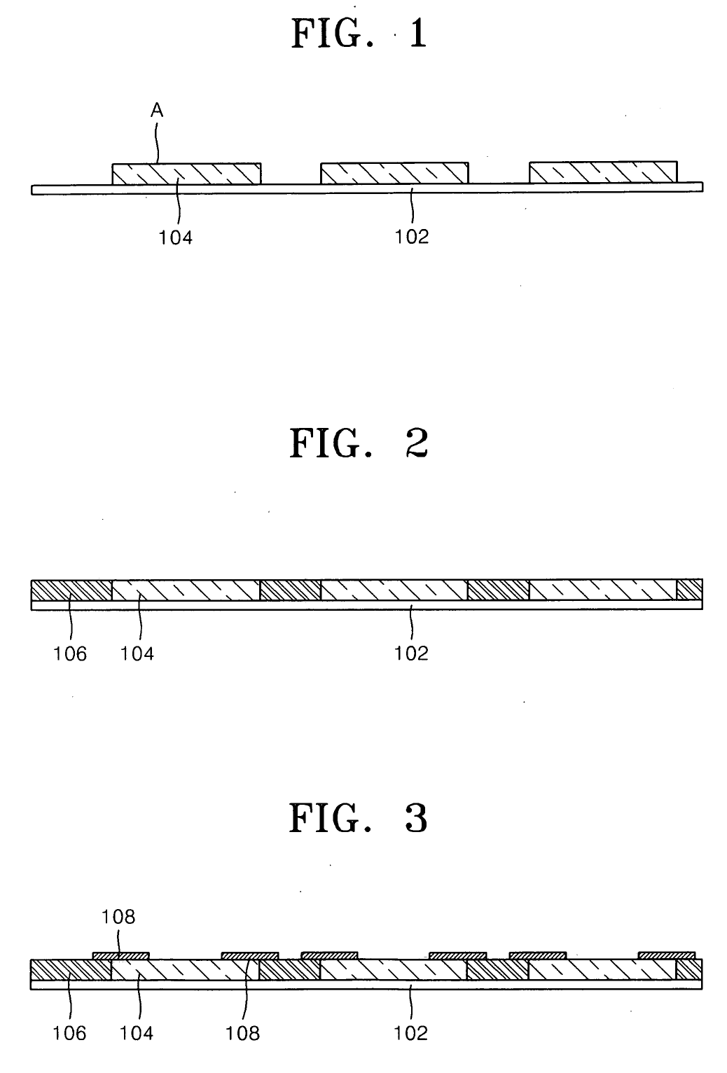

Referring to FIG. 2, a first encapsulation portion 106 that may have the same height as that of each of the first semiconductor chips 104 mounted on the carrier 102 may be formed between the first semiconductor chips 104. The first encapsulation portion 106 may be formed in one of the methods selected from among molding, printing, spin coating, and jetting methods. When the molding method is employed, epoxy mold compound (EMC) may be used as a material for the first encapsulation portion 106.

Referring to FIG. 3, a first wiring pattern 108 may be formed on the first encapsulation portion 106. The first wiring pattern 108 is preferably a multilayer film formed by sequentially depositing copper, gold, and nickel. The first wiring pattern 108 may be connected to bond pads (not shown) of the first semiconductor chips 104, and the first wiring pattern 108 may extend upward above the first encapsulation portion 106 in a fan shape. Thus, even when the interval between the bond pads in the first semiconductor chip 104 is designed to be narrow, since the bond pads may extend in a fan shape above the first encapsulation portion 106 through the first wiring pattern 108, design problems associated with narrow intervals between the bond pads may be solved, as the more efficient fan-out structure may still allow adequate electrical connection between the first semiconductor chip 104 and the first wiring pattern 108.

The fan-out structure signifies that the wiring pattern connecting to bond pads of a semiconductor chip may be allowed to extend beyond the mere surface of a semiconductor chip in order to afford an additional length of wiring pattern by which bond pads may electrically connect to the wiring. A fan-in structure signifies that the wiring pattern connecting to bond pads of a semiconductor are arranged within a more limited area which may be located directly above the semiconductor chip.

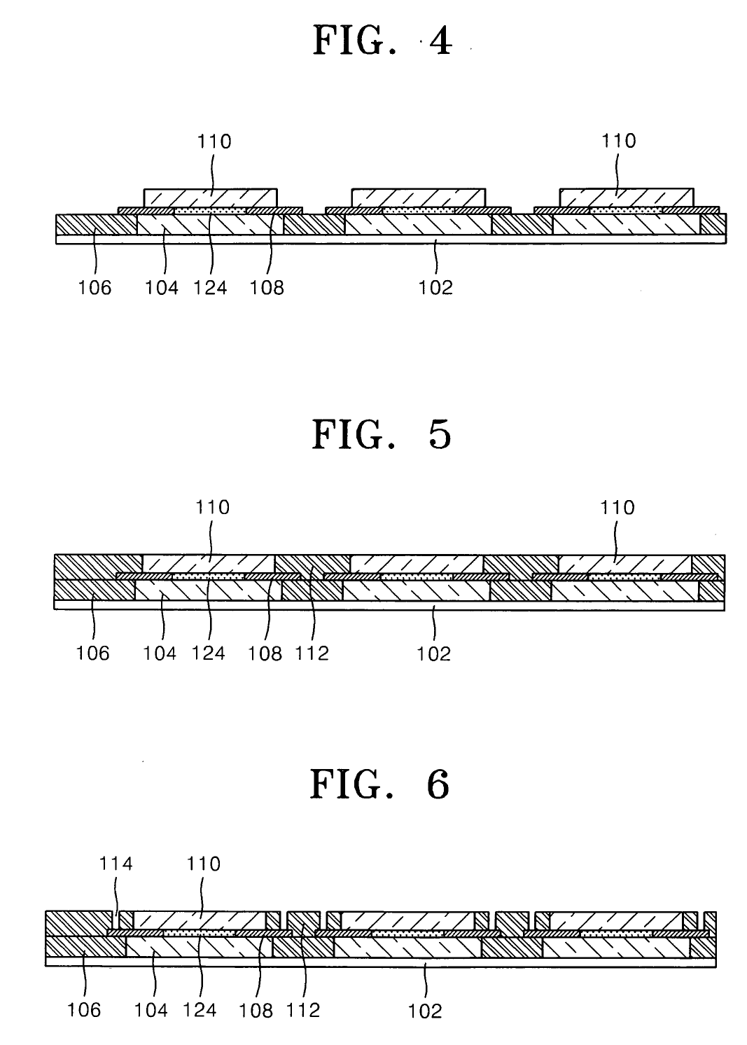

Referring to FIGS. 4 and 5, a second semiconductor chip 110 may be mounted using an adhesive member 124, the adhesive member 124 located on each of the first semiconductor chips 104 and between where the first wiring pattern 108 may be formed. Notice that the adhesive member 124 may allow the second semiconductor chip 110 to be mounted directly on top of the first semiconductor chip 104. The second semiconductor chip 110 is preferably mounted in such a manner that an active region with bond pads (not shown) may exist facing upward. A second encapsulation portion 112 that may have the same height as that of the second semiconductor chip 110 may be continuously formed at the edge of the second semiconductor chip 110. The second encapsulation portion 112 may be formed in the same manner as the first encapsulation portion 106.

Referring to FIGS. 6 to 8, a contact hole 114 for exposing the first wiring pattern 108 may be formed in the second encapsulation portion 112. The contact hole 114 may be formed using a method such as laser drilling or any other appropriate methods.

The contact hole 114 may be filled with a conductive material to form a via contact 118. A second wiring pattern 116 may be formed on the second semiconductor chip 110 and the second encapsulation portion 112. The second wiring pattern 116 preferably has the same shape as that of the first wiring pattern 108. The second wiring pattern 116 is preferably connected to bond pads of the second semiconductor chip 110 and may extend in a fan shape over the second encapsulation portion 112. Accordingly, each of the first semiconductor chips 104 and the second semiconductor chip 110 may be electrically connected to each other through the via contact 118 that may be provided in the second encapsulation portion 112.

The adhesive force of the adhesive layer that may exist on the carrier 102 may be weakened by applying heat or light to the adhesive layer of the carrier 102. Thus, the carrier 102 may be detached and removed from the bottom surface of the first semiconductor chip 104, as shown in FIG. 8. If the carrier 102 is formed of a metal material exhibiting a superior heat transfer characteristic, then the carrier 102 may not need to be removed. In this case, the carrier 102 may perform a function of a protective layer that may protect the bottom surfaces of the first semiconductor chips 104, which will be described below in detail with reference to FIG. 21.

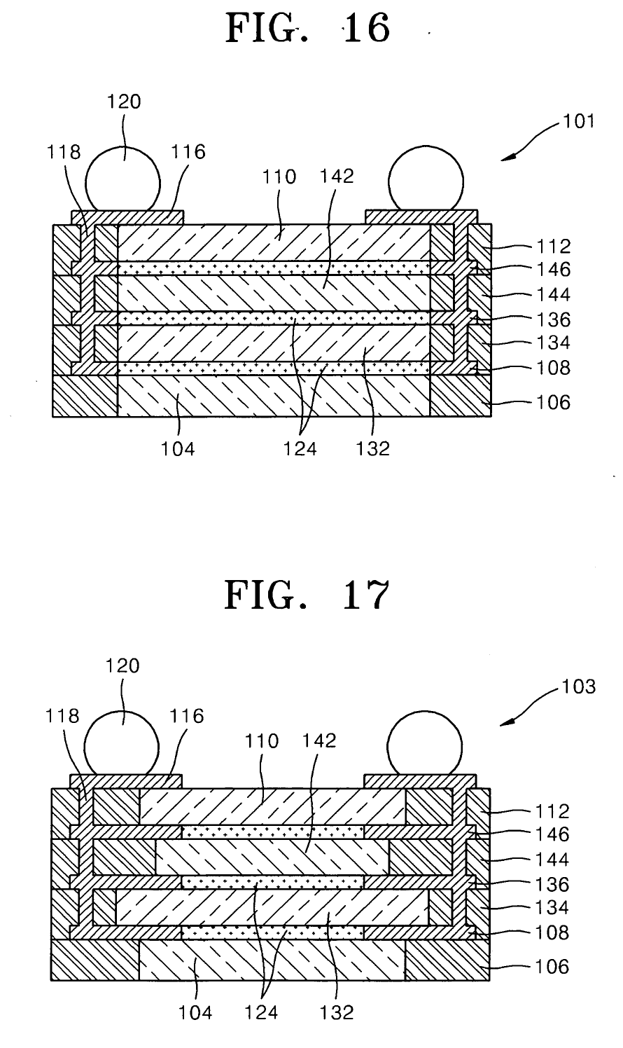

Also, additional processes of forming another semiconductor chip, another encapsulation portion, and another wiring pattern between the first and second semiconductor chips 104 and 110 may be performed. The size and thickness of each semiconductor chip may be designed to be the same or different from each other. For instance, when four semiconductor chips are to be deposited, the via contact 118 connecting the four semiconductor chips may be formed by making one single contact hole after the semiconductor chips are completed deposited and the second encapsulation portion 112 is formed. Also, in a modified example of the above method, the via contact 118 may be formed by depositing a semiconductor chip, forming an encapsulation portion that may have the same height, making three contact holes, and filling the contact holes with a conductive material. This method is described below, and shown in FIGS. 16-19.

Referring to FIG. 9, a protruding connection terminal, for example, a solder ball 120 or a bump, may be formed on the second wiring pattern 116. Then, a singulation process, which is a cutting process using a blade, may be performed so that a wafer level stacked package 100 according to example embodiments may be obtained.

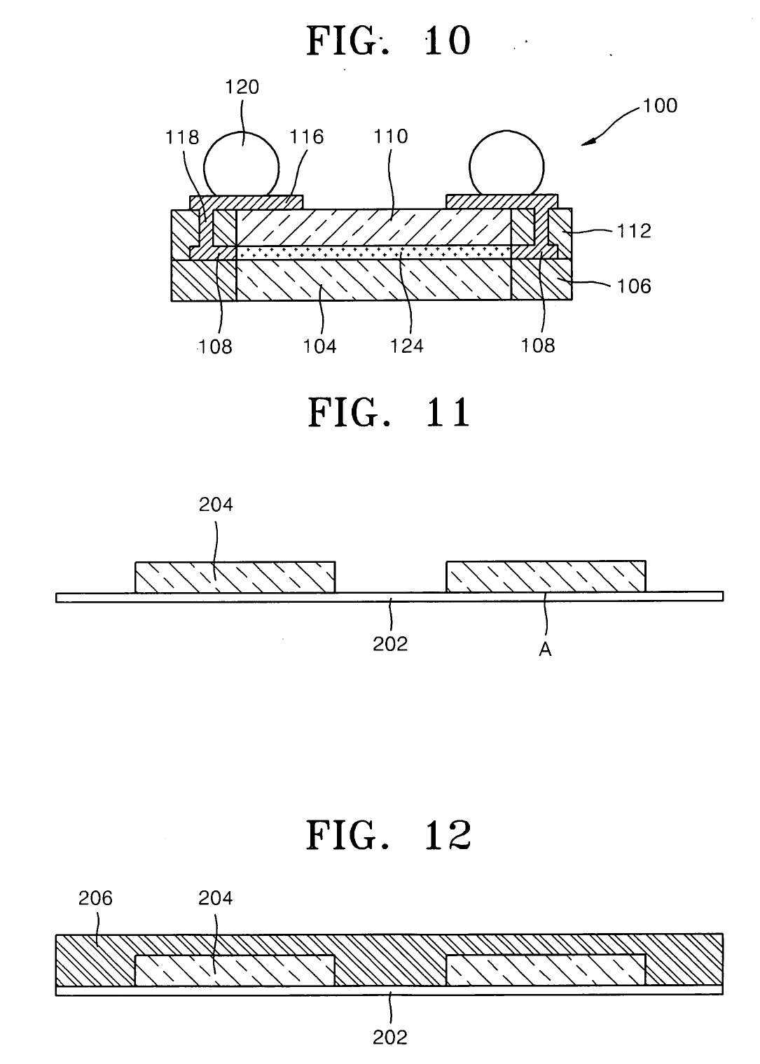

FIG. 10 is a cross-sectional view of the wafer level stacked package manufactured according to example embodiments. Referring to FIG. 10, the wafer level stacked package 100 with a via contact in an encapsulation portion according example embodiments may include the first semiconductor chip 104 having an active region facing upward, the first encapsulation portion 106 may be formed along the edge of the first semiconductor chip 104, and the first wiring pattern 108 may connect to the bond pads of the first semiconductor chip 104 located above the first semiconductor chip 104, the first wiring pattern 108 extending across the first encapsulation portion 106.

Also, the wafer level stacked package 100 may include the second semiconductor chip 110 on which an active region may be mounted on the first semiconductor chip 104 to face upward by means of the adhesive member 124, the second encapsulation portion 112 may be formed along the edge of the second semiconductor chip 110 above the first encapsulation portion 106, the second wiring pattern 116 may be connected to the bond pads of the second semiconductor chip 110 above the second semiconductor chip 110 and the second wiring pattern 116 may extend upward above the second encapsulation portion 112, the via contact 118 connecting the first wiring pattern 108 and the second wiring pattern 116 in the second encapsulation portion 112, and the solder ball 120 may be a protruding connection terminal attached to the second wiring pattern 116. The solder ball 120 may be replaced by a bump.

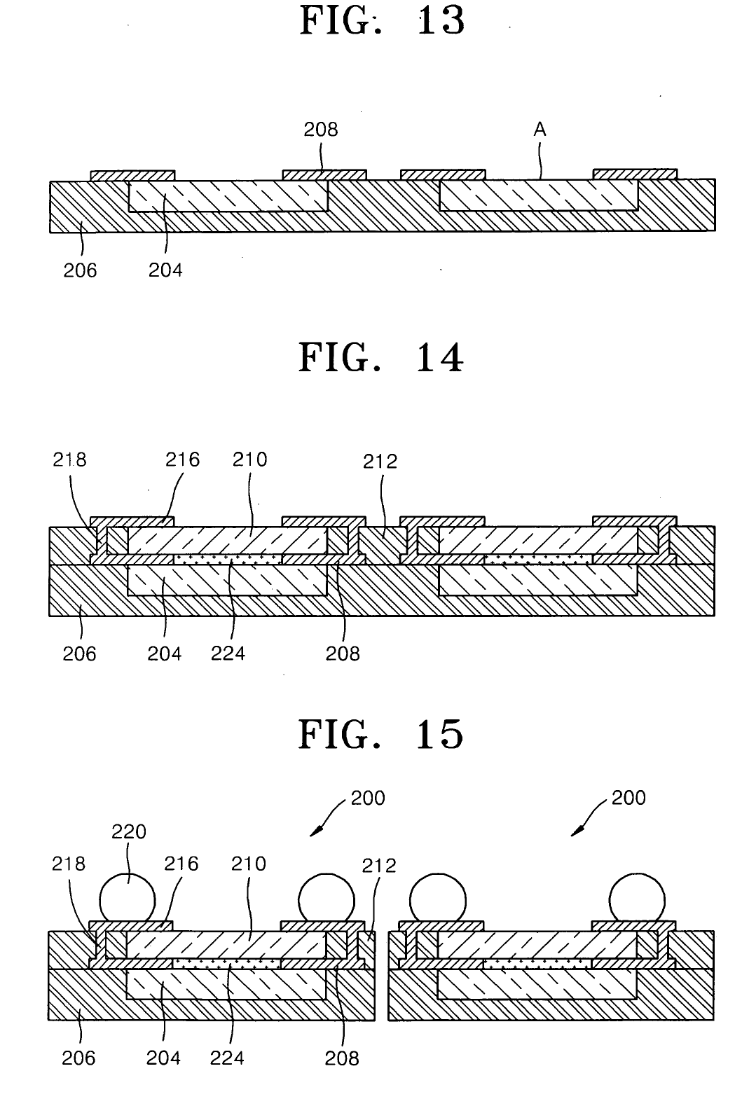

FIGS. 11 to 15 are cross-sectional views that show a method of manufacturing a wafer level stacked package with a via contact in an encapsulation portion according to example embodiments. Referring to FIGS. 11 to 15, a first semiconductor chip 204 may be mounted on a carrier 202 with an adhesive force in such a manner that an active region A of the semiconductor chip 204 may face down. Next, the first encapsulation portion 206 having a structure to sufficiently cover the side surface and the bottom surface of the first semiconductor chip 204 may be formed. The first encapsulation portion 206 may be formed in a molding process and an epoxy mold compound EMC may be used as a material thereof.

Then, the carrier 202 may be detached and removed from the first semiconductor chip 204 and the first encapsulation portion 206. Then, the first semiconductor chip 204 and the first encapsulation portion 206 may be flipped. Next, a first wiring pattern 208 may be formed on the active region of the first semiconductor chip 204 and the first encapsulation portion 206. The first wiring pattern 208 may have an extending fan shape as in the above-described first example embodiment such that problems which may be caused due to a fine pitch of the bond pad in the wafer level stacked package may be solved, and a fan-out structure may be implemented.

A second semiconductor chip 210 may be mounted on the first semiconductor chip 204 by using an adhesive member 224. Notice that the adhesive member 224 may allow the second semiconductor chip 210 to be mounted directly on the first semiconductor chip 204. The active region of the second semiconductor chip 210 is preferably mounted to face upward. A second encapsulation portion 212 that may have the same height as that of the second semiconductor chip 210 may be formed. A via contact 218 may be formed in the second encapsulation portion 212. The via contact 218 may be connected to a second wiring pattern 216 existing on the second semiconductor chip 210 and the second encapsulation portion 212 to electrically connect the first and second semiconductor chips 204 and 210. A solder ball 220 may be attached to the second wiring pattern 210 and a singulation process may be performed so that a wafer level stacked package 200 with a via contact in an encapsulation portion may be separated into pieces.

The wafer level stacked package 200, according to example embodiments, may have a structure similar to that of the wafer level stacked package 100 of the first embodiment. However, there may be a difference in that the first encapsulation portion 206 completely covers the bottom surface of the first semiconductor chip 204 and may not have the same height as that of the first semiconductor chip 204.

FIG. 16 illustrates a first modified example of a wafer level stacked package manufactured according to example embodiments. Referring to FIG. 16, although the number of deposited semiconductor chips in the first embodiment is two (104 and 110), in the present modified example two different semiconductor chips 132 and 142, two different encapsulation portions 134 and 144, and two different wiring patterns 136 and 146 may be additionally inserted.

Although four semiconductor chips 104, 110, 132, and 142 may be deposited in FIG. 16, the number of the semiconductor chips may be added or subtracted as necessary. It is advantageous that a wafer level stacked package 101 having the above structure may be applied to a semiconductor package made by depositing semiconductor chips that may have the same function as that of a semiconductor memory.

In the manufacturing of the wafer level stacked package 101, the via contact 118 may be formed in a method of forming all of four semiconductor chips and four encapsulation portions, making only one contact hole, and filling the contact hole with a conductive material. In an example embodiment, a modified method of separately forming a contact hole whenever a semiconductor chip and an encapsulation portion are deposited may also be implemented. Since the other structure and manufacturing method are already described in the description of the first embodiment, descriptions thereof will be omitted here.

FIG. 17 illustrates a second modified example of the wafer level stacked package manufactured according to example embodiments. Referring to FIG. 17, the size of a semiconductor chip does not matter in the wafer level stacked package 100 according to the first embodiment. However, in the present modified example embodiment, it is possible to deposit semiconductor chips 104, 132, 142, and 110 with different sizes, while electrically connecting the semiconductor chips 104, 132, 142, and 110 by means of the via contact 118. The semiconductor chips 104, 132, 142, and 110 may be a semiconductor chip performing a different function such as that of a microcontroller, a memory, and a logic circuit. A wafer level stacked package 103 having the above structure may be applied to a semiconductor package such as a system in package (SIP).

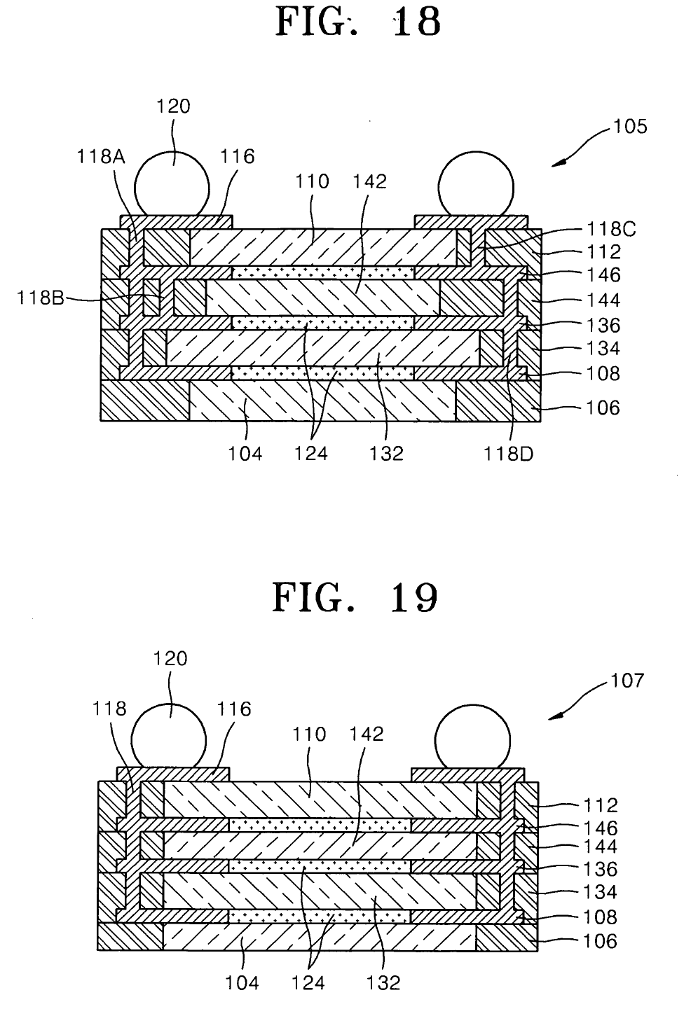

FIG. 18 illustrates another example embodiment. Similar to FIG. 17, when the four semiconductor chips 104, 132, 142, and 110 have different sizes, the semiconductor chips may be connected by a via contact 118 using a single, vertical connection path. However, when the semiconductor chips perform different functions, a circuit operation path may be more complicated, and therefore additional vertical connection paths may be provided to allow a plurality of via contacts 118A, 118B, 118C, and 118D, as in wafer level stacked package 105.

FIG. 19 illustrates a fourth modified example of the wafer level stacked package manufactured according to example embodiments. Although the thickness of the semiconductor chips 104 and 110 used in the wafer level stacked package 100 according to the first example embodiment may be the same, the semiconductor chips 104, 132, 142, and 110 having different thicknesses may be deposited to decrease the overall thickness, as in the wafer level stacked package 107 of the present example embodiment. The thicknesses of the encapsulation portions 106, 134, 144, and 112 formed at the side surfaces of the semiconductor chips 104, 132, 142, and 110 may be adjusted in proportion to the thicknesses of the semiconductor chips 104, 132, 142, and 110.

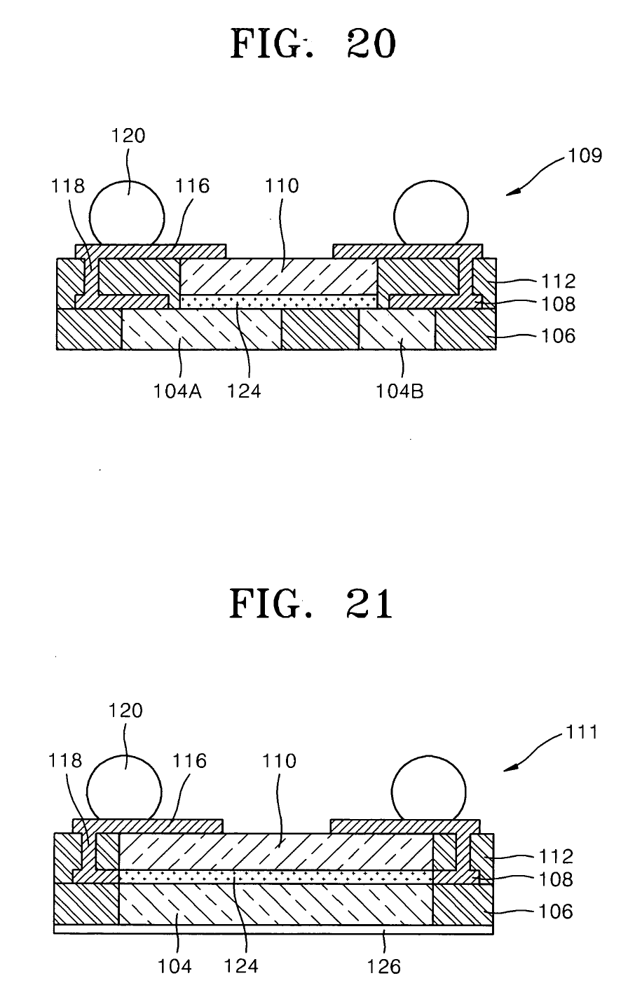

FIG. 20 illustrates a fifth modified example of the wafer level stacked package manufactured according to example embodiments. Although the wafer level stacked package 100 according to the first example embodiment uses one semiconductor chip 104 as the first semiconductor chip, a wafer level stacked package 109 according to the present modified example uses two semiconductor chips 104A and 104B that may be deposited in the same horizontal plane as each other. Although the two semiconductor chips 104A and 104B may have different sizes, they may be replaced by semiconductor chips performing the same function and having the same size. Also, in the modified example, one or two first semiconductor chips may be made. However, this may be modified so that two or more semiconductor chips 110 arranged in the middle or in the upper portion may be provided.

FIG. 21 illustrates a sixth modified example of the wafer level stacked package manufactured according to example embodiments. Referring to FIG. 18, the wafer level stacked package 100 according to the first example embodiment has no separate protective layer on the lower surface of the first semiconductor chip 104. However, a wafer level stacked package 111 of the present modified example may have a separate protective layer 126 formed on the bottom surfaces of the first semiconductor chip 104 and the first encapsulation portion 106. The protective layer 126 may be formed by using the carrier 102 of FIG. 1 used in the manufacturing process or by attaching a solid substrate that may have a superior heat transfer characteristic.

Thus, the protective layer 126 may work as a mechanical protection unit to buffer any physical impact on a lower end portion of the wafer level stacked package 111 and simultaneously act as a path to externally dissipate heat generated in the first and second semiconductor chips 104 and 110 when metal such as copper or aluminum exhibiting a heat transfer characteristic may be used as a material thereof.

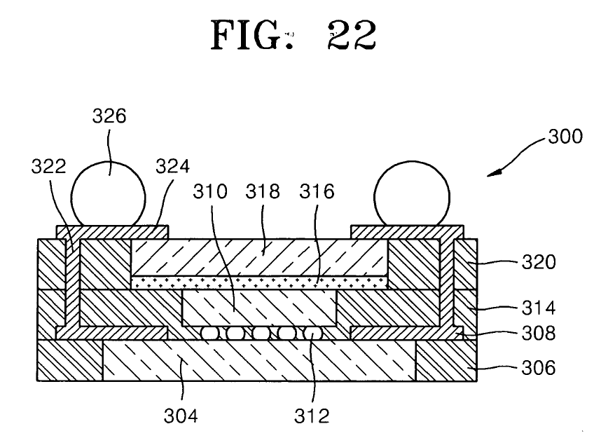

FIG. 22 is a cross-sectional view that explains a wafer level stacked package with a via contact in an encapsulation portion according to example embodiments. Referring to FIG. 22, a wafer level stacked package 300 according to the present embodiment characteristically may further include one or more semiconductor chips 310 that may be connected to a lower semiconductor chip through a bump 312, using for example the wafer level stacked packages 100 and 200 of FIGS. 10 and 15.

The wafer level stacked package 300 according to example embodiments include a first semiconductor chip 304 that may have an active region facing upward, a first encapsulation portion 306 that may be formed along the edge of the first semiconductor chip 304, a first wiring pattern 308 that may be connected to bond pads (not shown) of the first semiconductor chip 304 above the first semiconductor chip 304 and may extend upward above the first encapsulation portion 306, a second semiconductor chip 310 that may be electrically connected to the first semiconductor chip 304 through the bump 312 and that may have a size smaller than the first semiconductor chip 304, and a second encapsulation portion 314 that may be formed along the edge of the second semiconductor chip 310.

Also, the wafer level stacked package 300 according to example embodiments may include a third semiconductor chip 318 arranged on the second semiconductor chip 310 by means of an adhesive member 316 and that may have an active region mounted to face upward, a third encapsulation portion 320 that may be formed on the second encapsulation portion 314 along the edge of the third semiconductor chip 318, a third wiring pattern 324 that may be connected to bond pads of the third semiconductor chip 318 on the third semiconductor chip 318 and that may extend upward above the third encapsulation portion 320, a via contact 322 that may connect the first wiring pattern 308 and the third wiring pattern 324 in the second and third encapsulation portions 314 and 320, and a solder ball 326 that may be a protruding connection terminal attached to the third wiring pattern 324.

The wafer level stacked package 300 according to example embodiments may further include a separate protective layer (not shown in FIG. 22) under the first semiconductor chip 304, similar to the protective pattern 126 shown in FIG. 21. A method of manufacturing the wafer level stacked package 300 according to example embodiments is described below.

First, a plurality of the first semiconductor chips 304 may be mounted on a carrier (not shown) that may have an adhesive force such that the active region thereof may face upward. Then, the first encapsulation portion 306 having the same height as that of the first semiconductor chip may be formed on the carrier. The first wiring pattern 308 may be formed to connect to some of the bond pads of the first semiconductor chip 304, and the first wiring pattern 308 may extend upward above the first encapsulation portion 306. The second semiconductor chip 310 may be a size smaller than that of the first semiconductor chip 304 and may be connected via the bump 312 to the remaining bond pads of the first semiconductor chip 304, while the second semiconductor chip 310 may not be connected to the first wiring pattern 308 which may be mounted on the first semiconductor chip 304. The second encapsulation portion 314 may have the same height as that of the second semiconductor chip 310 and may be formed on the first encapsulation portion 306.

The third semiconductor chip 318 may be mounted on the second semiconductor chip 310, using an adhesive member 316, where the second encapsulation portion 314 may be formed in such a manner that the active region of the third semiconductor chip 318 may face upward. The third encapsulation portion 320 may have the same height as that of the third semiconductor chip 318 and the adhesive member 316, and the third encapsulation portion 320 may be formed on the second encapsulation portion 314. A contact hole to expose the first wiring pattern 308 may be formed in the second and third encapsulation portions 314 and 320. The via contact 322 may be formed by filling the contact hole with a conductive material. The third wiring pattern 324 may be connected to the bond pads of the third semiconductor chip 318, and may extend upward above the third encapsulation portion 320, and may be electrically connected to the via contact 322.

Finally, a protruding connection terminal such as a solder ball 326 may be attached to the third wiring pattern 324. The wafer level stacked package 300 according to example embodiments may be separated into pieces through a singulation process.

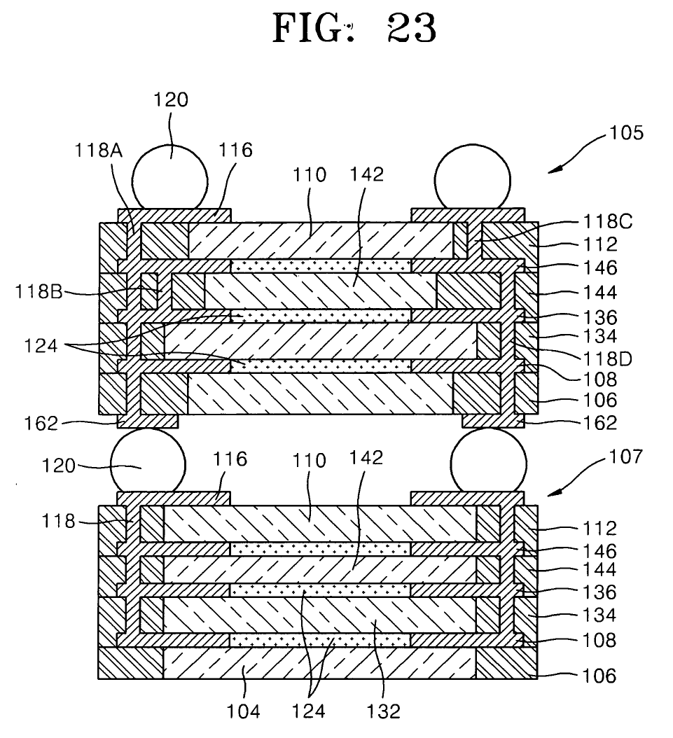

FIG. 23 is a cross-sectional view that illustrates an application of a modified example of the wafer level stacked package according to example embodiments. Referring to FIG. 23, one or more wafer level stacked packages such as the above-described wafer level stacked packages 100, 200, and 300 according to FIGS. 10, 15, and 22 may be vertically stacked. That is, when a larger number of semiconductor circuits need to be located in a limited area, while not being limited in terms of height, a package module may be implemented by vertically depositing one or more wafer level stacked packages 105 and 107. A wiring pattern 162 may be separately formed for the connection of the upper and lower wafer level stacked packages 105 and 107.

Therefore, according to example embodiments, first, the wafer level stacked package may achieve an effective fan-out structure because the upper and lower semiconductor chips may be connected through the wiring pattern in an extended fan-out structure and the wiring patterns may be integrally connected by means of the via contact. Also, an SIP may be easily implemented because a plurality of semiconductor chips may be vertically deposited regardless of the type, size, and thickness of the deposited semiconductor chip.

Second, the thickness of the wafer level stacked package may be reduced because wire bonding or flip chip bonding may not be used.

Third, production costs may be reduced and productivity may be improved because wire bonding, or a via contact penetrating the whole silicon with bond pads, may not be used.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A wafer level stacked package with a via contact in an encapsulation portion, the wafer level stacked package comprising:
a first semiconductor chip with an active region facing upward;
a first encapsulation portion formed along an edge of the first semiconductor chip;
a first wiring pattern connected to bond pads of the first semiconductor chip, the first wiring pattern formed above the first semiconductor chip and extending above the first encapsulation portion;
a second semiconductor chip mounted on the first semiconductor chip using an adhesive member, with an active region of the second semiconductor chip facing upward;
a second encapsulation portion formed along an edge of the second semiconductor chip, the second encapsulation portion located above the first encapsulation portion;
a second wiring pattern connected to bond pads of the second semiconductor chip, the second wiring pattern formed above the second semiconductor chip and extending above the second encapsulation portion; and
a via contact connecting the first wiring pattern and the second wiring pattern, the via contact formed in the second encapsulation portion.

2. The wafer level stacked package of claim 1, wherein the height of the first encapsulation portion is substantially the same as that of the first semiconductor chip.

3. The wafer level stacked package of claim 1, further comprising protruding connection terminals attached to the second wiring pattern.

4. The wafer level stacked package of claim 3, wherein the protruding connection terminals are one of a solder ball and a bump.

5. The wafer level stacked package of claim 1, further comprising one or more additional semiconductor chips located along the same horizontal plane as the first semiconductor chip.

6. The wafer level stacked package of claim 1, further comprising a protective layer formed on bottom surfaces of the first semiconductor chip and the first encapsulation portion.

7. The wafer level stacked package of claim 6, wherein the protective layer is formed of the same material as that of the first encapsulation portion.

8. The wafer level stacked package of claim 6, wherein the protective layer is formed of a material exhibiting a superior heat transfer characteristic as compared to the first encapsulation portion.

9. The wafer level stacked package of claim 1, further comprising one or more additional semiconductor chips, one or more additional encapsulation portions, and one or more additional wiring patterns that are connected through the via contact.

10. The wafer level stacked package of claim 9, wherein the sizes of the first semiconductor chip, the second semiconductor chip, and the one or more additional semiconductor chips are different from one another.

11. The wafer level stacked package of claim 9, wherein the thicknesses of the first semiconductor chip, the second semiconductor chip, and the one or more additional semiconductor chips are different from one another.

12. The wafer level stacked package of claim 10, wherein the via contact connecting the first wiring pattern, the second wiring pattern, and the one or more additional wiring patterns are connected through a plurality of paths.

13. A wafer level stacked package with a via contact in an encapsulation portion, the wafer level stacked package comprising:
a first semiconductor chip with an active region facing upward;
a first encapsulation portion formed along an edge of the first semiconductor chip;
a first wiring pattern connected to bond pads of the first semiconductor chip, the first wiring pattern formed above the first semiconductor chip and extending above the first encapsulation portion;
a second semiconductor chip electrically connected to the first semiconductor chip via a bump, the second semiconductor chip having a size smaller than the first semiconductor chip;
a second encapsulation portion formed along an edge of the second semiconductor chip;
a third semiconductor chip mounted above the second semiconductor chip such that an active region of the third semiconductor chip faces upward;
a third encapsulation portion formed along an edge of the third semiconductor chip above the second encapsulation portion;
a third wiring pattern connected to bond pads of the second semiconductor chip, the third wiring pattern formed above the third semiconductor chip and extending above the third encapsulation portion; and
a via contact connecting the first wiring pattern and the third wiring pattern, the via contact formed in the second and third encapsulation portions.

14. The wafer level stacked package of claim 13, further comprising protruding connection terminals attached to the third wiring pattern.

15. The wafer level stacked package of claim 13, further comprising a protective layer formed on bottom surfaces of the first semiconductor chip and the first encapsulation portion.

16. A method of manufacturing a wafer level stacked package with a via contact in an encapsulation portion, the method comprising:
mounting a plurality of first semiconductor chips on a carrier using an adhesive force such that an active region of the first semiconductor chip faces upward;
forming a first encapsulation portion having the same height as that of the first semiconductor chip on the carrier;
forming a first wiring pattern connected to bond pads of the first semiconductor chip, the first wiring pattern extending above the first encapsulation portion;
mounting a second semiconductor chip on the first semiconductor chip and the first wiring pattern, using an adhesive member, such that an active region of the second semiconductor chip faces upward;
forming a second encapsulation portion having the same height as that of the second semiconductor chip on the first encapsulation portion;
forming a via contact by forming a contact hole that exposes the first wiring pattern in the second encapsulation portion and filling the contact hole with a conductive material; and
forming a second wiring pattern connected to bond pads of the second semiconductor chip, the second wiring pattern extending above the second encapsulation portion and electrically connected to the via contact.

17. The method of claim 16, wherein the first and second encapsulation portions are formed by a method selected from molding, printing, spin coating, and jetting methods.

18. The method of claim 16, wherein the contact hole is formed using a laser drilling method.

19. The method of claim 16, further comprising removing the carrier from the wafer level stacked package.

20. The method of claim 16, wherein the carrier is formed of a material exhibiting a superior heat transfer characteristic as compared to the material of the first encapsulation portion.

21. The method of claim 16, further comprising attaching the protruding connection terminals to the second wiring pattern.

22. The method of claim 16, further comprising forming another semiconductor chip, another encapsulation portion, and another wiring pattern between the first and second semiconductor chips.

23. The method of claim 22, wherein the sizes of the first semiconductor chip, the second semiconductor chip, and the other semiconductor chip are different from one another.

24. The method of claim 22, wherein the thicknesses of the first semiconductor chip, the second semiconductor chip, and the other semiconductor chip are different from one another.

25. The method of claim 22, wherein the via contact connects the first wiring pattern, the other wiring pattern, and the second wiring pattern using one or more paths.

26. The method of claim 16, further comprising one or more additional semiconductor chips, in the same horizontal plane as the first semiconductor chip, are connected to the second semiconductor chip.

27. The method of claim 22, wherein the via contact is formed using a one-time contact hole forming process after the second encapsulation portion is formed.

28. The method of claim 22, wherein a separate via contact is formed after another encapsulation portion is formed on the first encapsulation portion, and the via contact is formed after the second encapsulation portion is formed.

29. The method of claim 21, further comprising separating a wafer level stacked package through a singulation process.

30. The method of claim 16, further comprising forming a protective layer on bottom surfaces of the first semiconductor chip and the first encapsulation portion.

31. The method of claim 30, wherein the protective layer is formed of a material exhibiting a superior heat transfer characteristic as compared to the material of the first encapsulation portion.

32. A method of manufacturing a wafer level stacked package with a via contact in an encapsulation portion, the method comprising:
mounting a first semiconductor chip on a carrier such that an active region of the first semiconductor chip faces downward;
forming a first encapsulation portion completely covering the first semiconductor chip on the carrier;
removing the carrier and arranging the active region of the first semiconductor chip to face upward;
forming a first wiring pattern connected to bond pads of the first semiconductor chip and extending above the first encapsulation portion;
mounting a second semiconductor chip on the first semiconductor chip and the first wiring pattern, using an adhesive member, such that an active region of the second semiconductor chip faces upward;
forming a second encapsulation portion having the same height as that of the second semiconductor chip on the first encapsulation portion;
forming a via contact by forming a contact hole that exposes the first wiring pattern in the second encapsulation portion and filling the contact hole with a conductive material; and
forming a second wiring pattern connected to bond pads of the second semiconductor chip, the second wiring pattern extending above the second encapsulation portion and electrically connected to the via contact.

33. The method of claim 32, further comprising attaching protruding connection terminals to the second wiring pattern.

34. The method of claim 32, further comprising forming another semiconductor chip, another encapsulation portion, and another wiring pattern between the first and second semiconductor chips.

35. The method of claim 33, further comprising separating a wafer level stacked package using a singulation process.

36. A method of manufacturing a wafer level stacked package with a via contact in an encapsulation portion, the method comprising:
mounting a plurality of first semiconductor chips on a carrier such that an active region of the first semiconductor chip faces upward, the first semiconductor having a plurality of bond pads;
forming a first encapsulation portion having the same height as that of the first semiconductor chip on the carrier;
forming a first wiring pattern connected to one or more of the plurality of bond pads of the first semiconductor chip, the first wiring pattern extending above the first encapsulation portion;
mounting a second semiconductor chip above the first semiconductor chip, the second semiconductor having a size smaller than that of the first semiconductor chip, the second semiconductor connected one or more of the bond pads of the first semiconductor chip that are not connected to the first wiring pattern;
forming a second encapsulation portion having the same height as that of the second semiconductor chip, the second encapsulation portion located above the first encapsulation portion;
mounting a third semiconductor chip above the second semiconductor chip, such that an active region of the third semiconductor chip faces upward;
forming a third encapsulation portion having the same height as that of the third semiconductor chip, the second encapsulation portion located above the second encapsulation portion;
forming a via contact by forming a contact hole that exposes the first wiring pattern in the second and third encapsulation portions and filling the contact hole with a conductive material; and
forming a third wiring pattern connected to bond pads of the third semiconductor chip, the third wiring pattern extending above the third encapsulation portion and electrically connected to the via contact.

37. The method of claim 36, further comprising forming protruding connection terminals attached to the third wiring pattern.

38. The method of claim 37, further comprising separating a wafer level stacked package through a singulation process.

39. The wafer level stacked package of claim 13, wherein the third semiconductor chip is mounted directly on the second semiconductor chip using an adhesive member.
